(19) United States
(12) Patent Application Publication
(10) Pub. No.: US 2024/0324378 A1
(43) Pub. Date: Sep. 26, 2024

(54) DISPLAY PANEL

(71) Applicant: Samsung Display Co., Ltd., Yongin-si (KR)

(72) Inventors: Sangshin Lee, Yongin-si (KR); Yeonju Kang, Yongin-si (KR); Sanghoon Kim, Yongin-si (KR); Seungjin Lee, Yongin-si (KR); Minji Jang, Yongin-si (KR)

(73) Assignee: Samsung Display Co., Ltd., Yongin-si (KR)

(21) Appl. No.: 18/434,198

(22) Filed: Feb. 6, 2024

(30) Foreign Application Priority Data
Mar. 24, 2023 (KR) 10-2023-0039052
Jun. 16, 2023 (KR) 10-2023-0077712

(51) Int. Cl. H10K 59/35

(52) U.S. Cl. CPC H10K 59/352; H10K 59/353

(57) ABSTRACT

A display panel includes unit pixel areas arranged in a first direction and a second direction perpendicular to the first direction, wherein in a first unit pixel area, a first emission area, a second emission area, and a third emission area are arranged in a first arrangement pattern such that lines connecting respective centers thereof form a triangle, in a second unit pixel area, the first to third emission areas are arranged in a second arrangement pattern top-bottom symmetrical to the first arrangement pattern, in a third unit pixel area, the first to third emission areas are arranged in a third arrangement pattern left-right symmetrical to the first arrangement pattern, in a fourth unit pixel area, the first to third emission areas are arranged in a fourth arrangement pattern top-bottom symmetrical to the third arrangement pattern, and the first to third emission areas have a closed curve shape.

### CROSS-REFERENCE TO RELATED APPLICATION(S)

This application claims priority under 35 U.S.C. § 119 to and benefits of Korean Patent Application No. 10-2023-0039052, filed on Mar. 24, 2023, and Korean Patent Application No. 10-2023-0077712, filed on Jun. 16, 2023, in the Korean Intellectual Property Office, the entire contents of which are incorporated herein by reference.

### BACKGROUND

### 1. Technical Field

One or more embodiments relate to a display panel and a display apparatus including the display panel.

### 2. Description of the Related Art

Recently, display apparatuses have been used for various purposes. Also, as display apparatuses have become thinner and lighter in weight, the usage range has widened.

As display apparatuses are used in various ways, various methods may be used to design the shapes of display apparatuses, and further, more functions may be combined or associated with display apparatuses.

### SUMMARY

One or more embodiments provide a display apparatus with improved display quality and a display apparatus including the display panel.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a display panel may include unit pixel areas arranged in a first direction and a second direction perpendicular to the first direction, wherein a first display element emitting light of a first color, a second display element emitting light of a second color, and a third display element emitting light of a third color may be arranged in each of the unit pixel areas, the unit pixel areas may include a first unit pixel area and a second unit pixel area alternately arranged in the first direction and a third unit pixel area and a fourth unit pixel area respectively adjacent to the first unit pixel area and the second unit pixel area in the second direction, in the first unit pixel area, a first emission area corresponding to the first display element, a second emission area corresponding to the second display element, and a third emission area corresponding to the third display element may be arranged in a first arrangement pattern such that virtual lines connecting respective centers of the first, second, and third emission areas may form a triangle, in the second unit pixel area, the first emission area, the second emission area, and the third emission area are arranged in a second arrangement pattern, which is top-bottom symmetrical to the first arrangement pattern, in the third unit pixel area, the first emission area, the second emission area, and the third emission area may be arranged in a third arrangement pattern, which is left-right symmetrical to the first arrangement pattern, in the fourth unit pixel area, the first emission area, the second emission area, and the third emission area may be arranged in a fourth arrangement pattern, which is top-bottom symmetrical to the third arrangement pattern, and each of the first emission area, the second emission area, and the third emission area has a closed curve shape.

In an embodiment, the first emission area and the second emission area may be arranged adjacent to each other in the first direction, and the third emission area may be arranged adjacent to the first emission area and the second emission area in the second direction.

In an embodiment, a size of the third emission area may be greater than a size of the first emission area and a size of the second emission area.

In an embodiment, the size of the first emission area and the size of the second emission area may be substantially equal to each other.

In an embodiment, the size of the first emission area and the size of the second emission area may be different from each other.

In an embodiment, the first emission area in the second unit pixel area and the first emission area in the third unit pixel area may be arranged adjacent to each other between the third emission area in the first unit pixel area and the third emission area in the fourth unit pixel area.

In an embodiment, an emission layer of the first display element in the second unit pixel area and an emission layer of the first display element in the third unit pixel area may be integral with each other.

In an embodiment, a distance between the third emission area in the first unit pixel area and the third emission area in the fourth unit pixel area may be greater than a distance between the first emission area in the second unit pixel area and the first emission area in the third unit pixel area.

In an embodiment, an angle between a virtual straight line connecting a center of the third emission area in the first unit pixel area and a center of the third emission area in the fourth unit pixel area and a virtual straight line connecting a center of the first emission area in the second unit pixel area and a center of the first emission area in the third unit pixel area may be in a range of about 80° to about 100°.

In an embodiment, the first unit pixel area may include a (1-1)th unit pixel area and a (1-2)th unit pixel area spaced apart from each other in the first direction, the second unit pixel area may include a (2-1)th unit pixel area arranged between the (1-1)th unit pixel area and the (1-2)th unit pixel area, the third unit pixel area may include a (3-1)th unit pixel area and a (3-2)th unit pixel area respectively adjacent to the (1-1)th unit pixel area and the (1-2)th unit pixel area in the second direction, the fourth unit pixel area may include a (4-1)th unit pixel area adjacent to the (2-1)th unit pixel area in the second direction, the first emission area in the (2-1)th unit pixel area and the first emission area in the (3-1)th unit pixel area may be arranged to be adjacent to each other between the third emission area in the (1-1)th unit pixel area and the third emission area in the (4-1)th unit pixel area, and the second emission area in the (2-1)th unit pixel area and the second emission area in the (3-2)th unit pixel area may be arranged to be adjacent to each other between the third emission area in the (1-2)th unit pixel area and the third emission area in the (4-1)th unit pixel area.

In an embodiment, an emission layer of the first display element in the (2-1)th unit pixel area and an emission layer of the first display element in the (3-1)th unit pixel area may be integral with each other, and an emission layer of the second display element in the (2-1)th unit pixel area and an emission layer of the second display element in the (3-2)th unit pixel area may be integral with each other.

In an embodiment, a virtual line connecting centers of the first emission area in the (2-1)th unit pixel area and the first emission area in the (3-1)th unit pixel area may be arranged in a first oblique direction, and a virtual line connecting centers of the second emission area in the (2-1)th unit pixel area and the second emission area in the (3-2)th unit pixel area may be arranged in a second oblique direction intersecting the first oblique direction.

In an embodiment, the first emission area in the first unit pixel area, the second emission area in the first unit pixel area, and the third emission area in the second unit pixel area may be arranged in a virtual line in the first direction, the third emission area in the first unit pixel area, the first emission area in the second unit pixel area, and the second emission area in the second unit pixel area may be arranged in a virtual line in the first direction, the second emission area in the third unit pixel area, the first emission area in the third unit pixel area, and the third emission area in the fourth unit pixel area may be arranged in a virtual line in the first direction, and the third emission area in the third unit pixel area, the second emission area in the fourth unit pixel area, and the first emission area in the fourth unit pixel area may be arranged in a virtual line in the first direction.

In an embodiment, the first emission area in the first unit pixel area and the second emission area in the third unit pixel area may be arranged in a virtual line in the second direction, the third emission area in the first unit pixel area and the third emission area in the third unit pixel area may be arranged in a virtual line in the second direction, the second emission area in the first unit pixel area and the first emission area in the third unit pixel area may be arranged in a virtual line in the first direction, the first emission area in the second unit pixel area and the second emission area in the fourth unit pixel area may be arranged in a virtual line in the second direction, the third emission area in the second unit pixel area and the third emission area in the fourth unit pixel area may be arranged in a virtual line in the second direction, and the second emission area in the second unit pixel area and the first emission area in the fourth unit pixel area may be arranged in a virtual line in the second direction.

According to one or more embodiments, a display panel may include unit pixel areas defined in a first direction and a second direction perpendicular to the first direction, wherein a first display element emitting light of a first color, a second display element emitting light of a second color, and a pair of third display elements emitting light of a third color may be arranged in each of the unit pixel areas, the unit pixel areas include a first unit pixel area and a second unit pixel area alternately arranged in the second direction, in the first unit pixel area, a first emission area corresponding to the first display element and a second emission area corresponding to the second display element may be arranged adjacent to each other in a first diagonal direction and a pair of third emission areas respectively corresponding to the pair of third display elements may be arranged adjacent to each other in a second diagonal direction, in the second unit pixel area, the first emission area and the second emission area may be arranged adjacent to each other in the second diagonal direction and the pair of third emission areas may be arranged adjacent to each other in the first diagonal direction, a third emission area among the pair of third emission areas in the first unit pixel area and a third emission area among the pair of third emission areas in the second unit pixel area may be arranged adjacent to each other in the second direction, the first emission area has a size smaller than a size of the second emission area and each of the pair of third emission areas has a size greater than the size of the first emission area and smaller than the size of the second emission area, and each of the first emission area, the second emission area, and the pair of third emission areas has a closed curve shape.

In an embodiment, a sum of the sizes of the pair of third emission areas may be greater than the size of the first emission area and greater than the size of the second emission area.

In an embodiment, each of the pair of third emission areas may have an elliptical shape.

In an embodiment, one third emission area among the pair of third emission areas in the first unit pixel area may have a long axis arranged in the first direction, and another third emission area among the pair of third emission areas in the first unit pixel area may have a long axis arranged in the second direction.

In an embodiment, third emission areas, which are arranged adjacent to each other and disposed in the first unit pixel area and the second unit pixel area, may respectively have long axes in different directions.

In an embodiment, third emission areas arranged adjacent to each other in the first unit pixel area and the second unit pixel area may respectively have long axes in a same direction.

In an embodiment, each of the first emission area and the second emission area may have a circular shape.

In an embodiment, the second emission area in the first unit pixel area and the second emission area in the second unit pixel area may be arranged adjacent to each other in the second direction.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view schematically illustrating a display apparatus according to an embodiment;

FIGS. 2, 3, and 4 are schematic cross-sectional views schematically illustrating a portion of a cross-section of a display apparatus according to an embodiment;

FIG. 5 is a schematic plan view illustrating an arrangement of pixels arranged in a display area of a display panel according to an embodiment;

FIGS. 6, 7, and 8 are schematic plan views illustrating some components of a display panel according to an embodiment;

FIG. 9 is a schematic plan view illustrating an arrangement of pixels arranged in a display area of a display panel according to an embodiment;

FIG. 10 is a schematic plan view illustrating some components of a display panel according to an embodiment;

FIG. 11 is a schematic plan view illustrating an arrangement of pixels arranged in a display area of a display panel according to an embodiment;

FIG. 12 is a schematic plan view illustrating some components of a display panel according to an embodiment; and

FIGS. 13 and 14 are schematic plan views illustrating an arrangement of pixels arranged in a display area of a display panel according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z—axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

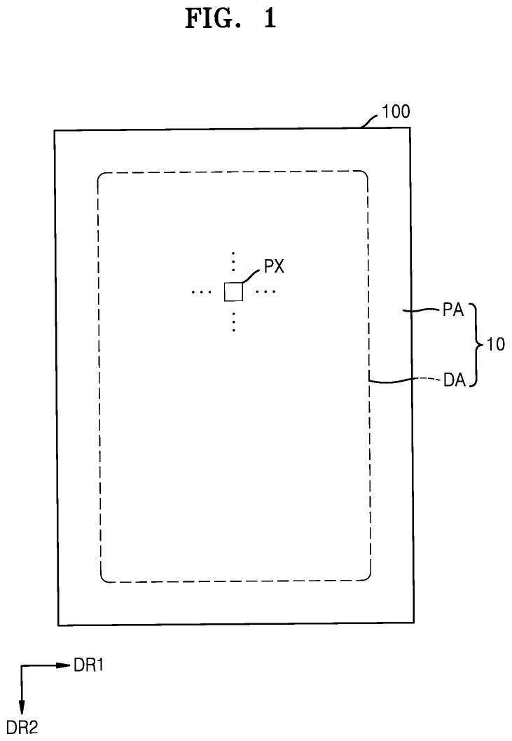

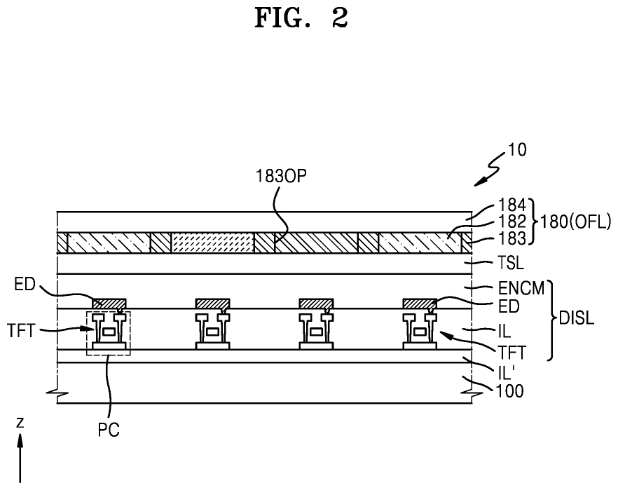

FIG. 1 is a schematic plan view schematically illustrating a display apparatus according to an embodiment. FIGS. 2, 3, and 4 are schematic cross-sectional views schematically illustrating a portion of a cross-section of a display apparatus according to an embodiment.

Referring to FIG. 1, the display apparatus may include a display panel 10, and a cover window protecting the display panel 10 may be further disposed over the display panel 10.

The display panel 10 may include a display area DA displaying an image and a peripheral area PA outside the display area DA. The peripheral area PA may be a non-display area in which pixels PX are not arranged. The display area DA may be surrounded (e.g., entirely surrounded) by the peripheral area PA. Various components forming the display panel 10 may be disposed over a substrate 100. Thus, the substrate 100 may include the display area DA and the peripheral area PA.

A plurality of pixels PX may be arranged in the display area DA. The pixel PX may include a display element. The display element may be connected to a pixel circuit driving the pixel PX. In an embodiment, the display element may be an organic light emitting diode OLED. Each pixel PX may emit, for example, red light, green light, blue light, or white light through the organic light emitting diode OLED.

In a plan view, the display area DA may have a rectangular shape as illustrated in FIG. 1. In other embodiments, the display area DA may have a polygonal shape (e.g., a triangular shape, a pentagonal shape, or a hexagonal shape), a circular shape, an elliptical shape, an atypical shape, or the like.

The peripheral area PA may be an area arranged around the display area DA and may be an area in which an image is not displayed. Various lines for transmitting electrical signals to be applied to the display area DA, peripheral circuits electrically connected to pixel circuits, and/or pads to which a printed circuit board or a driver IC chip is attached may be positioned in the peripheral area PA.

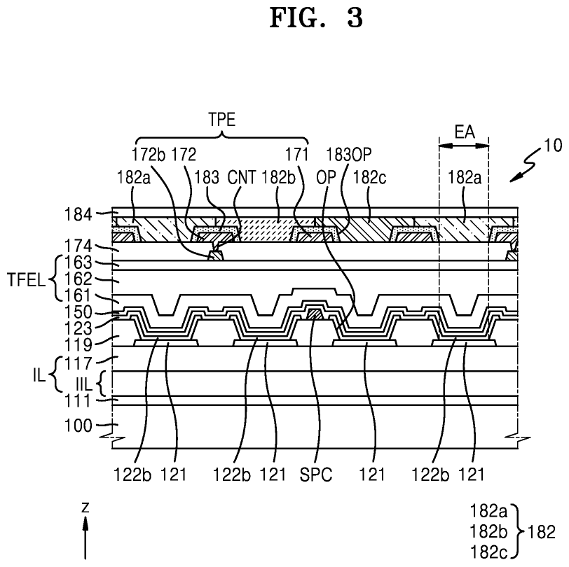

Referring to FIGS. 2 and 3, the display panel 10 may include a substrate 100, a display layer DISL over the substrate 100, a touch screen layer TSL, and an optical functional layer OFL.

The display layer DISL may include a pixel circuit PC including a thin film transistor, a light emitting element ED as a display element, and an encapsulation member ENCM such as a thin film encapsulation layer TFEL or an encapsulation substrate. Insulating layers IL and IL′ may be arranged in the display layer DISL and between the substrate 100 and the display layer DISL. For convenience of illustration, the pixel circuit PC is omitted in FIG. 3.

The substrate 100 may include a single layer including a glass material. In another example, the substrate 100 may include a polymer resin. The substrate 100 including a polymer resin may have a multilayer structure in which an organic layer and an inorganic layer including a polymer resin are stacked. The substrate 100 may include a rigid substrate or a flexible substrate capable of bending, folding, rolling, or the like.

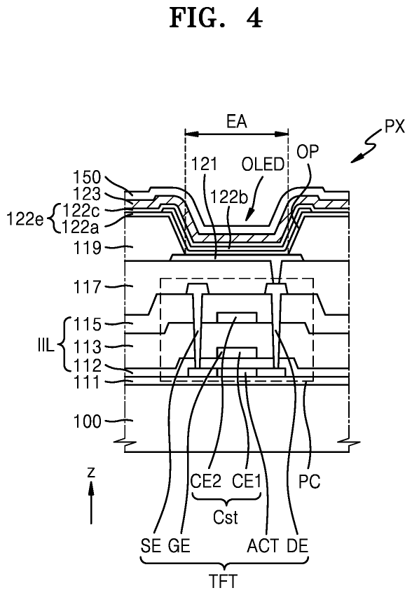

A buffer layer 111, an inorganic insulating layer IIL, and a planarization layer 117 may be sequentially stacked over the substrate 100. The planarization layer 117 may include an organic material or an inorganic material and may have a single-layer structure or a multiple-layer structure. The pixel circuit PC may be arranged between the buffer layer 111 and the planarization layer 117. As illustrated in FIG. 4, the pixel circuit PC may include a thin film transistor TFT and a capacitor Cst.

The thin film transistor TFT may include a semiconductor layer ACT including an organic semiconductor material such as amorphous silicon, polycrystalline silicon, or an oxide semiconductor, a gate electrode GE, a source electrode SE, and a drain electrode DE. The capacitor Cst may include a lower electrode CE1 and an upper electrode CE2.

The semiconductor layer ACT may be disposed over the buffer layer 111. A first insulating layer 112 may be arranged between the semiconductor layer ACT and the gate electrode GE. A second insulating layer 113 may be disposed over the gate electrode GE, and the upper electrode CE2 of the capacitor Cst may be disposed over the second insulating layer 113. The upper electrode CE2 may overlap the gate electrode GE thereunder. The gate electrode GE and the upper electrode CE2 overlapping each other with the second insulating layer 113 between the gate electrode GE and the upper electrode CE2 may form the capacitor Cst. The gate electrode GE may be the lower electrode CE1 of the capacitor Cst. A third insulating layer 115 may be disposed over the capacitor Cst, and the source electrode SE and the drain electrode DE may be disposed over the third insulating layer 115.

Each of the first insulating layer 112, the second insulating layer 113, and the third insulating layer 115 may include an inorganic material such as silicon oxide, silicon nitride, and/or silicon oxynitride. The first insulating layer 112, the second insulating layer 113, and the third insulating layer 115 may be referred to as the inorganic insulating layer IIL.

The buffer layer 111 including an inorganic material such as silicon oxide, silicon nitride, and/or silicon oxynitride may be arranged between the thin film transistor TFT and the substrate 100.

The planarization layer 117 may be disposed over the thin film transistor TFT. The planarization layer 117 may include, for example, an organic insulating material such as acryl, benzocyclobutene (BCB), or hexamethyldisiloxane (HMDSO). Moreover, the planarization layer 117 may include an inorganic insulating material such as silicon oxide (SiOx), silicon nitride (SiNx), silicon oxynitride (SiOxNy), aluminum oxide (Al₂O₃), titanium oxide (TiO₂), tantalum oxide (Ta₂O₅), hafnium oxide (HfO₂), or zinc oxide (ZnO₂). In case that the planarization layer 117 is formed, after a layer is formed, chemical mechanical polishing may be performed on an upper surface of the layer to provide a flat upper surface. The planarization layer 117 may include a single layer or multiple layers.

As a light emitting element ED, an organic light emitting diode OLED that is a display element may be disposed over the planarization layer 117. The organic light emitting diode OLED may include a pixel electrode 121, an opposite electrode 123, and an intermediate layer between the pixel electrode 121 and the opposite electrode 123.

The pixel electrode 121 may be disposed over the planarization layer 117, and the pixel electrode 121 may be electrically connected to the thin film transistor TFT by contacting the source electrode SE or the drain electrode DE through a via hole of the planarization layer 117.

A pixel definition layer 119 may be disposed over the planarization layer 117. The pixel definition layer 119 may cover an edge portion of the pixel electrode 121 and may include an opening OP exposing a portion of the pixel electrode 121. The size and shape of an emission area EA of the organic light emitting diode OLED may be defined by the opening OP.

The pixel definition layer 119 may include a transparent insulating material or an opaque insulating material. In an embodiment, the pixel definition layer 119 may include an organic insulating material such as polyimide, polyamide, acrylic resin, benzocyclobutene, hexamethyldisiloxane (HMDSO), or phenolic resin. In other embodiments, the pixel definition layer 119 may include an inorganic insulating material such as silicon nitride or silicon oxide or may include an organic insulating material and an inorganic insulating material.

In some embodiments, the pixel definition layer 119 may include a light blocking material and may be formed in black. The light blocking material may include, for example, a resin or paste including carbon black, carbon nanotube, or black dye, metal particles (e.g., nickel, aluminum, molybdenum, or any alloy thereof), metal oxide particles (e.g., chromium oxide), or metal nitride particles (e.g., chromium nitride). In case that the pixel definition layer 119 includes a light blocking material, the reflection of external light by metal structures disposed under the pixel definition layer 119 may be reduced.

As illustrated in FIG. 3, a spacer SPC may be further formed over the pixel definition layer 119. In an embodiment, the spacer SPC and the pixel definition layer 119 may include the same material. For example, the pixel definition layer 119 and the spacer SPC may be formed together in a mask process by using a halftone mask or the like, and thus, the spacer SPC may have an island shape (or isolated shape) protruding from the pixel definition layer 119 by a certain distance in the z-axis direction. The z-axis direction may be perpendicular to each of a first direction DR1 and a second direction DR2. In another example, the spacer SPC may include a different material than the pixel definition layer 119. For example, the spacers SPC may include island-shaped insulating patterns arranged at certain intervals over the pixel definition layer 119.

As illustrated in FIG. 4, the intermediate layer may include an emission layer 122b and an organic functional layer 122e over and/or under the emission layer 122b.

Emission layers 122b may be arranged in the opening OP of the pixel definition layer 119 to correspond to (or to overlap) the pixel electrode 121. The emission layer 122b may include a high molecular weight material or a low molecular weight material and may emit red, green, blue, or white light.

The organic functional layer 122e may include a first functional layer 122a and/or a second functional layer 122c. The first functional layer 122a or the second functional layer 122c may be omitted.

The first functional layer 122a may be disposed under the emission layer 122b. The first functional layer 122a may include a single layer or multiple layers including an organic material. The first functional layer 122a may include a hole transport layer (HTL) having a single-layer structure. In another example, the first functional layer 122a may include a hole injection layer (HIL) and a hole transport layer (HTL). The first functional layer 122a may be integrally formed to correspond to (or to overlap) the organic light emitting diodes OLED included in the display area DA.

The second functional layer 122c may be disposed over the emission layer 122b. The second functional layer 122c may include a single layer or multiple layers including an organic material. The second functional layer 122c may include an electron transport layer (ETL) and/or an electron injection layer (EIL). The second functional layer 122c may be integrally formed to correspond to (or to overlap) the organic light emitting diodes OLED included in the display area DA.

The opposite electrode 123 may be disposed over the emission layer 122b. An upper layer 150 including an organic material may be disposed over the opposite electrode 123.

In an embodiment, the intermediate layer may include two or more emission units sequentially stacked between the pixel electrode 121 and the opposite electrode 123 and a charge generation layer (CGL) arranged between two emission units. In case that the intermediate layer includes an emission unit and a charge generation layer (CGL), the organic light emitting diode OLED may be a tandem light emitting element. Because the organic light emitting diode OLED has a stack structure of a plurality of emission units, the color purity and the light emission efficiency thereof may be improved.

An emission unit (e.g., single emission unit) may include an emission layer and a first functional layer and a second functional layer under and over the emission layer, respectively. The charge generation layer (CGL) may include a negative charge generation layer and a positive charge generation layer. The light emission efficiency of the organic light emitting diode OLED that is a tandem light emitting element including a plurality of emission layers may be further improved by the negative charge generation layer and the positive charge generation layer. The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

The upper layer 150 may be provided to protect the opposite electrode 123 and improve light extraction efficiency. The upper layer 150 may include lithium fluoride (LiF). In another example, the upper layer 150 may further include an inorganic insulating material such as silicon oxide (SiOx) or silicon nitride (SiNx).

The display elements may be covered by the thin film encapsulation layer TFEL. In an embodiment, the thin film encapsulation layer TFEL may include at least one inorganic encapsulation layer and at least one organic encapsulation layer. For example, the thin film encapsulation layer TFEL may include first and second inorganic encapsulation layers 161 and 163 and an organic encapsulation layer 162 between the first and second inorganic encapsulation layers 161 and 163.

The touch screen layer TSL may be disposed over the second inorganic encapsulation layer 163. The touch screen layer TSL may obtain coordinate information according to an external input, for example, a touch event. The touch screen layer TSL may sense an external input by using a self-capacitance method or a mutual capacitance method. The touch screen layer TSL may include touch electrodes TPE and lines connected to the touch electrodes TPE. The touch electrodes TPE may include first touch electrodes 171 and second touch electrodes 172. The first touch electrodes 171 may be connected by connection electrodes arranged on the same layer. The second touch electrodes 172 may be connected through a contact hole CNT of an insulating layer 174 to connection electrodes 172b arranged on a different layer. The touch electrodes TPE may be positioned to correspond to (or to overlap) the pixel definition layer 119.

The optical functional layer OFL may include a filter layer 180 including a color filter 182, a black matrix 183, and an overcoat layer 184. The black matrix 183 may cover the first touch electrodes 171 and the second touch electrodes 172. The black matrix 183 may be positioned to correspond to (or to overlap) the pixel definition layer 119. The overcoat layer 184 may include an organic material such as resin, and the organic material may be transparent.

In the display panel 10 including the color filter 182 and the black matrix 183 as the optical functional layer OFL instead of a polarization plate or a polarization film, the light emission efficiency of the display elements may be improved, and thus the effects of power consumption reduction and luminance increase may be achieved. Accordingly, the lifetime of the display panel may be improved. Further, the same or higher luminance/lifetime may be ensured even with a smaller area than the existing emission area. Further, because a polarization plate or a polarization film itself is not used, the thickness of the display panel may be reduced.

The color filter 182 may include a first color filter 182a selectively transmitting only light of a first color, a second color filter 182b selectively transmitting only light of a second color, and a third color filter 182c selectively transmitting only light of a third color. The first color filter 182a, the second color filter 182b, and the third color filter 182c may be arranged to correspond to (or to overlap) the emission area EA of the pixel PX. The first color filter 182a, the second color filter 182b, and the third color filter 182c may be arranged adjacent to each other. Each of the first color filter 182a, the second color filter 182b, and the third color filter 182c may have an independent pattern structure. Each of the first color filter 182a, the second color filter 182b, and the third color filter 182c may be arranged in an opening 1830P of the black matrix 183. Each of the first color filter 182a, the second color filter 182b, and the third color filter 182c may partially overlap the pixel definition layer 119.

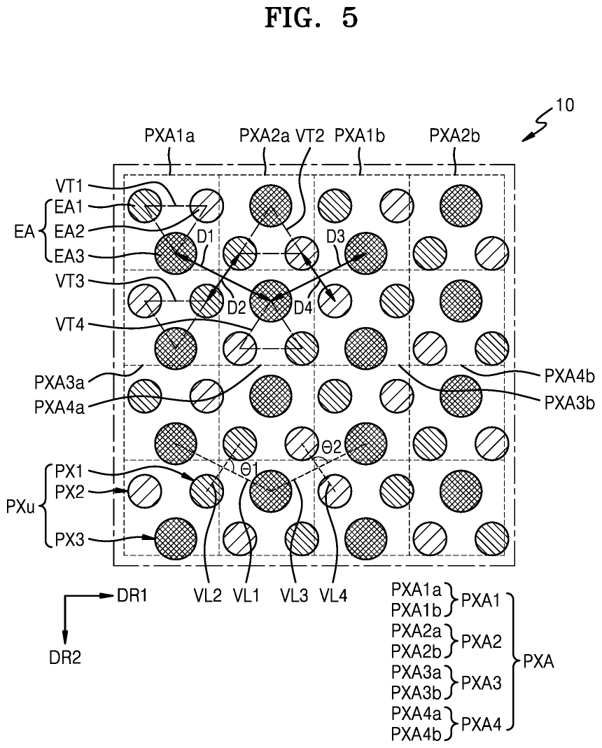

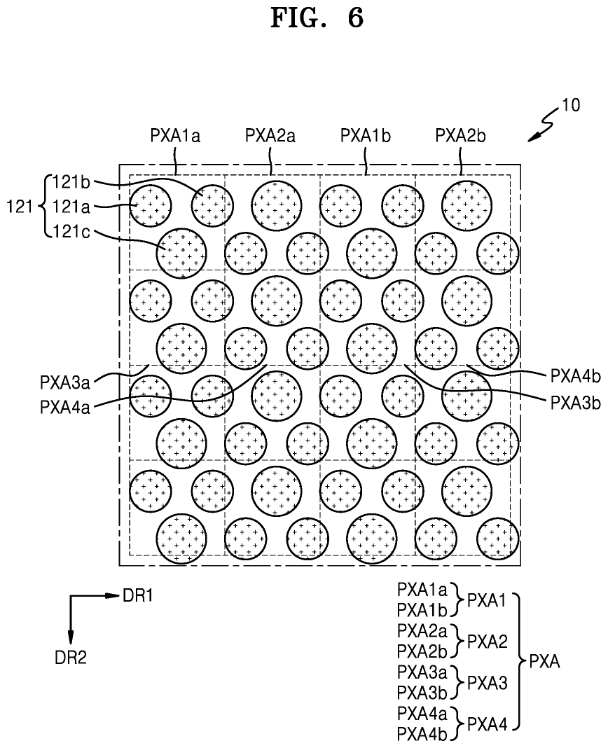

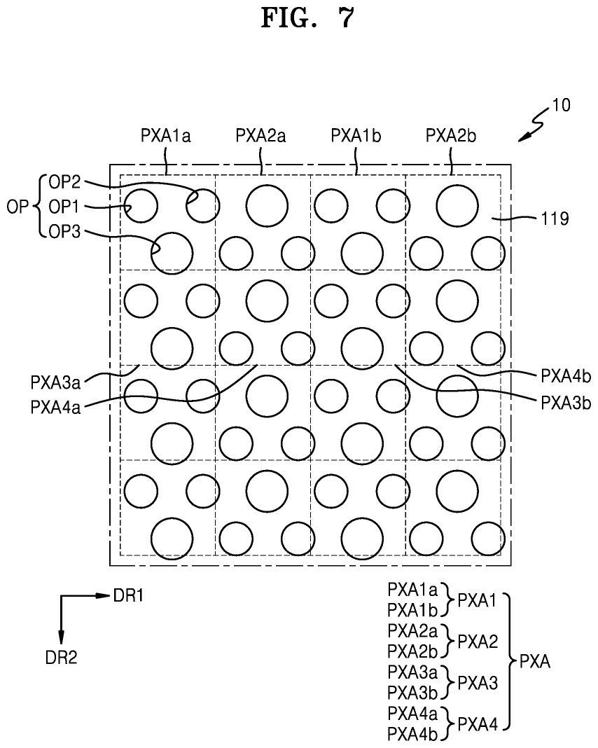

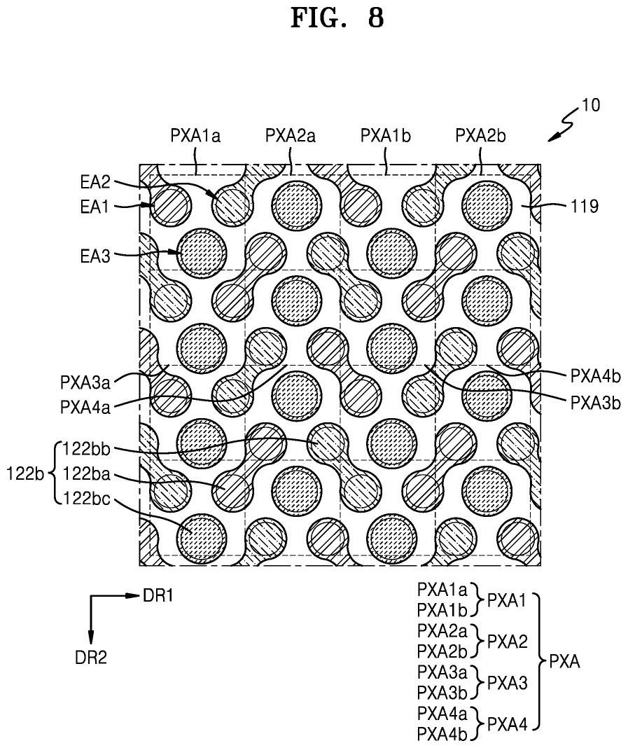

FIG. 5 is a schematic plan view illustrating an arrangement of pixels arranged in a display area of a display panel according to an embodiment. FIG. 5 illustrates emission areas EA corresponding to a first display element of a first pixel PX1, a second display element of a second pixel PX2, and a third display element of a third pixel PX3. FIGS. 6, 7 and 8 are schematic plan views illustrating some components of a display panel according to an embodiment. FIG. 6 illustrates an arrangement of the pixel electrode 121. FIG. 7 illustrates an arrangement of the pixel definition layer 119 and the openings OP of the pixel definition layer 119. FIG. 8 illustrates an arrangement of the emission layer 122b.

Referring to FIGS. 5, 6, 7, and 8, unit pixel areas PXA may be defined (or arranged) in the first direction DR1 and the second direction DR2 in the display area DA (see FIG. 1) of the display panel 10, and a unit pixel PXu may be arranged in each unit pixel area PXA. The unit pixel PXu may include a first pixel PX1, a second pixel PX2, and a third pixel PX3. In the unit pixel area PXA, display elements of the first pixel PX1, the second pixel PX2, and the third pixel PX3 may be arranged in a certain pattern according to a certain rule.

The first pixel PX1, the second pixel PX2, and the third pixel PX3 may emit light of different colors. Each of the first pixel PX1, the second pixel PX2, and the third pixel PX3 may be one of a red pixel emitting red light, a blue pixel emitting blue light, and a green pixel emitting green light. For example, the first pixel PX1 may be a red pixel emitting red light, the second pixel PX2 may be a blue pixel emitting blue light, and the third pixel PX3 may be a green pixel emitting green light. However, embodiments are not limited thereto, and the first pixel PX1, the second pixel PX2, and the third pixel PX3 may be modified in various combinations. For example, the first pixel PX1 may be a green pixel emitting green light, the second pixel PX2 may be a red pixel emitting red light, and the third pixel PX3 may be a blue pixel emitting blue light. Each of the first pixel PX1, the second pixel PX2, and the third pixel PX3 may include an organic light emitting diode OLED that is a display element and a pixel circuit to which the organic light emitting diode OLED is connected.

The size and shape of an emission area EA of the organic light emitting diode OLED may be defined by the opening OP of the pixel definition layer 119 described above with reference to FIG. 4, and the emission area EA may be an area in which the emission layer 122b (see FIG. 4) of the organic light emitting diode OLED is arranged. Thus, the arrangement (or disposition) of pixels may refer to the arrangement (or disposition) of display elements, the arrangement (or disposition) of pixel electrodes, or the arrangement (or disposition) of emission areas.

The emission area EA may include a first emission area EA1 corresponding to the first display element of the first pixel PX1, a second emission area EA2 corresponding to the second display element of the second pixel PX2, and a third emission area EA3 corresponding to the third display element of the third pixel PX3. Each of the first to third emission areas EA1, EA2, and EA3 may have a closed curve shape. For example, each of the first to third emission areas EA1, EA2, and EA3 may have a circular shape, an elliptical shape, or the like. A reflective color band and diffraction phenomenon may be minimized by implementing the first to third emission areas EA1, EA2, and EA3 in a closed curve shape.

The area (or size) of the third emission area EA3 may be greater than the area (or size) of the first emission area EA1 and the area (or size) of the second emission area EA2. In an embodiment, the area (or size) of the first emission area EA1 may be substantially equal to the area (or size) of the second emission area EA2. However, embodiments are not limited thereto. In another example, the area (or size) of the first emission area EA1 may be different from the area (or size) of the second emission area EA2.

The unit pixel areas PXA may include a first unit pixel area PXA1 and a second unit pixel area PXA2 alternately arranged in the first direction DR1 and may include a third unit pixel area PXA3 adjacent to the first unit pixel area PXA1 in the second direction DR2 and a fourth unit pixel area PXA4 adjacent to the second unit pixel area PXA1 in the second direction DR2.

In the first to fourth unit pixel areas PXA1, PXA2, PXA3, and PXA4, the first display element of the first pixel PX1, the second display element of the second pixel PX2, and the third display element of the third pixel PX3 may be arranged such that virtual lines connecting the respective centers of the first, second, and third display elements may form a triangle.

In each of the first to fourth unit pixel areas PXA1, PXA2, PXA3, and PXA4, the virtual lines connecting the centers of the first emission area EA1, the second emission area EA2, and the third emission area EA3 may be arranged to form a triangle.

In the first unit pixel area PXA1, the first emission area EA1, the second emission area EA2, and the third emission area EA3 may be arranged in a first arrangement pattern such that the virtual lines connecting the respective centers thereof may form a first virtual triangle VT1.

In the second unit pixel area PXA2, the first emission area EA1, the second emission area EA2, and the third emission area EA3 may be arranged in a second arrangement pattern, which is top-bottom symmetrical to the first arrangement pattern. For example, in the second unit pixel area PXA2, the first emission area EA1, the second emission area EA2, and the third emission area EA3 may be arranged such that the virtual lines connecting the respective centers thereof may form a second virtual triangle VT2, which is top-bottom symmetrical to the first virtual triangle VT1. In the third unitpixel area PXA3, the first emission area EA1, the second emission area EA2, and the third emission area EA3 may be arranged in a third arrangement pattern, which is left-right symmetrical to the first arrangement pattern. For example, in the third unit pixel area PXA3, the first emission area EA1, the second emission area EA2, and the third emission area EA3 may be arranged such that the virtual lines connecting the respective centers thereof may form a third virtual triangle VT3, which is left-right symmetrical to the first virtual triangle VT1. In the fourth unit pixel area PXA4, the first emission area EA1, the second emission area EA2, and the third emission area EA3 may be arranged in a fourth arrangement pattern, which is top-bottom symmetrical to the third arrangement pattern. For example, in the fourth unit pixel area PXA4, the first emission area EA1, the second emission area EA2, and the third emission area EA3 may be arranged such that the virtual lines connecting the respective centers thereof may form a fourth virtual triangle VT4, which is top-bottom symmetrical to the third virtual triangle VT3. In an embodiment, the fourth arrangement pattern may be top-bottom symmetrical to the third arrangement pattern and may be left-right symmetrical to the second arrangement pattern.

In the first unit pixel area PXA1, the first emission area EA1 and the second emission area EA2 may be arranged adjacent to each other in the first direction DR1. In the first unit pixel area PXA1, the third emission area EA3 may be arranged adjacent to the first emission area EA1 and the second emission area EA2 in the second direction DR2. In the first unit pixel area PXA1, the third emission area EA3 may be spaced apart from the first emission area EA1 and the second emission area EA2 in the second direction DR2.

In the second unit pixel area PXA2, the first emission area EA1 and the second emission area EA2 may be arranged adjacent to each other in the first direction DR1. In the second unit pixel area PXA2, the third emission area EA3 may be arranged adjacent to the first emission area EA1 and the second emission area EA2 in the second direction DR2. In the second unit pixel area PXA2, the third emission area EA3 may be spaced apart from the first emission area EA1 and the second emission area EA2 in a direction opposite to the second direction DR2.

The first emission area EA1 in the first unit pixel area PXA1, the second emission area EA2 in the first unit pixel area PXA1, and the third emission area EA3 in the second unit pixel area PXA2 may be arranged in a virtual line in the first direction DR1. The first emission area EA1 in the first unit pixel area PXA1, the second emission area EA2 in the first unit pixel area PXA1, and the third emission area EA3 in the second unit pixel area PXA2 may be arranged in order in the first direction DR1. The second emission area EA2 in the first unit pixel area PXA1 may be arranged between the first emission area EA1 in the first unit pixel area PXA1 and the third emission area EA3 in the second unit pixel area PXA2. The third emission area EA3 in the first unit pixel area PXA1, the first emission area EA1 in the second unit pixel area PXA2, and the second emission area EA2 in the second unit pixel area PXA2 may be arranged in a virtual line in the first direction DR1. The third emission area EA3 in the first unit pixel area PXA1, the first emission area EA1 in the second unit pixel area PXA2, and the second emission area EA2 in the second unit pixel area PXA2 may be arranged in order in the first direction DR1. The first emission area EA1 in the second unit pixel area PXA2 may be arranged between the third emission area EA3 in the first unit pixel area PXA1 and the second emission area EA2 in the second unit pixel area PXA2.

In the third unit pixel area PXA3, the first emission area EA1 and the second emission area EA2 may be arranged adjacent to each other in the first direction DR1. In the third unit pixel area PXA3, the third emission area EA3 may be arranged adjacent to the first emission area EA1 and the second emission area EA2 in the second direction DR2. In the third unit pixel area PXA3, the third emission area EA3 may be spaced apart from the first emission area EA1 and the second emission area EA2 in the second direction DR2.

The first emission area EA1 in the first unit pixel area PXA1 and the second emission area EA2 in the third unit pixel area PXA3 may be arranged in a virtual line in the second direction DR2. The third emission area EA3 in the first unit pixel area PXA1 and the third emission area EA3 in the third unit pixel area PXA3 may be arranged in a virtual line in the second direction DR2. The second emission area EA2 in the first unit pixel area PXA1 and the first emission area EA1 in the third unit pixel area PXA3 may be arranged in a virtual line in the second direction DR2.

In the fourth unit pixel area PXA4, the first emission area EA1 and the second emission area EA4 may be arranged adjacent to each other in the first direction DR1. In the fourth unit pixel area PXA4, the third emission area EA3 may be arranged adjacent to the first emission area EA1 and the second emission area EA2 in the second direction DR2. In the fourth unit pixel area PXA4, the third emission area EA3 may be spaced apart from the first emission area EA1 and the second emission area EA2 in a direction opposite to the second direction DR2.

The second emission area EA2 in the third unit pixel area PXA3, the first emission area EA1 in the third unit pixel area PXA3, and the third emission area EA3 in the fourth unit pixel area PXA4 may be arranged in a virtual line in the first direction DR1. The second emission area EA2 in the third unit pixel area PXA3, the first emission area EA1 in the third unit pixel area PXA3, and the third emission area EA3 in the fourth unit pixel area PXA4 may be arranged in order in the first direction DR1. The first emission area EA1 in the third unit pixel area PXA3 may be arranged between the second emission area EA2 in the third unit pixel area PXA3 and the third emission area EA3 in the fourth unit pixel area PXA4. The third emission area EA3 in the third unit pixel area PXA3, the second emission area EA2 in the fourth unit pixel area PXA4, and the first emission area EA1 in the fourth unit pixel area PXA4 may be arranged in a virtual line in the first direction DR1. The third emission area EA3 in the third unit pixel area PXA3, the second emission area EA2 in the fourth unit pixel area PXA4, and the first emission area EA1 in the fourth unit pixel area PXA4 may be arranged in order in the first direction DR1. The second emission area EA2 in the fourth unit pixel area PXA4 may be arranged between the third emission area EA3 in the third unit pixel area PXA3 and the first emission area EA1 in the fourth unit pixel area PXA4.

The first emission area EA1 in the second unit pixel area PXA2 and the second emission area EA2 in the fourth unit pixel area PXA4 may be arranged in a virtual line in the second direction DR2. The third emission area EA3 in the second unit pixel area PXA2 and the third emission area EA3 in the fourth unit pixel area PXA4 may be arranged in a virtual line in the second direction DR2. The second emission area EA2 in the second unit pixel area PXA2 and the first emission area EA1 in the fourth unit pixel area PXA4 may be arranged in a virtual line in the second direction DR2.

The first emission area EA1 in the second unit pixel area PXA2 and the first emission area EA1 in the third unit pixel area PXA3 may be arranged adjacent to each other between the third emission area EA3 in the first unit pixel area PXA1 and the third emission area EA3 in the fourth unit pixel area PXA4.

A distance D1 between the center of the third emission area EA3 in the first unit pixel area PXA1 and the center of the third emission area EA3 in the fourth unit pixel area PXA4 may be greater than a distance D2 between the center of the first emission area EA1 in the second unit pixel area PXA2 and the center of the first emission area EA1 in the third unit pixel area PXA3.

A first virtual line VL1 connecting the center of the third emission area EA3 in the first unit pixel area PXA1 and the center of the third emission area EA3 in the fourth unit pixel area PXA4 and a second virtual line VL2 connecting the center of the first emission area EA1 in the second unit pixel area PXA2 and the center of the first emission area EA1 in the third unit pixel area PXA3 may intersect each other. The first virtual line VL1 may be arranged in a first oblique direction. The first oblique direction may be an oblique direction between the first direction DR1 and the second direction DR2. The second virtual line VL2 may be arranged in a second oblique direction intersecting the first oblique direction. The angle between the second oblique direction and the first oblique direction may be about 80° to about 100°. The angle between the second oblique direction and the first direction DR1 may be greater than about 0° and less than about 90°. The second oblique direction may be referred to as a fourth direction. An angle θ between the first virtual line VL1 and the second virtual line VL2 may be about 80° to about 1000.

The first unit pixel area PXA1 may include a (1-1)th unit pixel area PXA1a and a (1-2)th unit pixel area PXA1b spaced apart from each other in the first direction DR1. The second unit pixel area PXA2 may include a (2-1)th unit pixel area PXA2a and a (2-2)th unit pixel area PXA2b spaced apart from each other in the first direction DR1. The (2-1)th unit pixel area PXA2a may be arranged between the (1-1)th unit pixel area PXA1a and the (1-2)th unit pixel area PXA1b.

The third unit pixel area PXA3 may include a (3-1)th unit pixel area PXA3a and a (3-2)th unit pixel area PXA3b spaced apart from each other in the first direction DR1. The (3-1)th unit pixel area PXA3a may be adjacent to the (1-1)th unit pixel area PXA1a in the second direction DR2. The (3-2)th unit pixel area PXA3b may be adjacent to the (1-2)th unit pixel area PXA1b in the second direction DR2. The fourth unit pixel area PXA4 may include a (4-1)th unit pixel area PXA4a and a (4-2)th unit pixel area PXA4b spaced apart from each other in the first direction DR1. The (4-1)th unit pixel area PXA4a may be arranged between the (3-1)th unit pixel area PXA3a and the (3-2)th unit pixel area PXA3b. The (4-1)th unit pixel area PXA4a may be adjacent to the (2-1)th unit pixel area PXA2a in the second direction DR2. The (4-2)th unit pixel area PXA4b may be adjacent to the (2-2)th unit pixel area PXA2b in the second direction DR2.

The first emission area EA1 in the (2-1)th unit pixel area PXA2a and the first emission area EA1 in the (3-1)th unit pixel area PXA3a may be arranged adjacent to each other between the third emission area EA3 in the (1-1)th unit pixel area PXA1a and the third emission area EA3 in the (4-1)th unit pixel area PXA4a.

A first virtual line VL1 connecting the center of the third emission area EA3 in the (1-1)th unit pixel area PXA1a and the center of the third emission area EA3 in the (4-1)th unit pixel area PXA4a and a second virtual line VL2 connecting the center of the first emission area EA1 in the (2-1)th unit pixel area PXA2a and the center of the first emission area EA1 in the (3-1)th unit pixel area PXA3a may intersect each other. An angle θ1 between the first virtual line VL1 and the second virtual line VL2 may be about 80° to about 100°.

The second emission area EA2 in the (2-1)th unit pixel area PXA2a and the second emission area EA2 in the (3-2)th unit pixel area PXA3b may be arranged adjacent to each other between the third emission area EA3 in the (1-2)th unit pixel area PXA1b and the third emission area EA3 in the (4-1)th unit pixel area PXA4a.

A distance D1 between the center of the third emission area EA3 in the (1-1)th unit pixel area PXA1a and the center of the third emission area EA3 in the (4-1)th unit pixel area PXA4a may be greater than a distance D2 between the center of the first emission area EA1 in the (2-1)th unit pixel area PXA2a and the center of the first emission area EA1 in the (3-1)th unit pixel area PXA3a. A distance D3 between the center of the third emission area EA3 in the (1-2)th unit pixel area PXA1b and the center of the third emission area EA3 in the (4-1)th unit pixel area PXA4a may be greater than a distance D4 between the center of the second emission area EA2 in the (2-1)th unit pixel area PXA2a and the center of the second emission area EA2 in the (3-2)th unit pixel area PXA3b.

A third virtual line VL3 connecting the center of the third emission area EA3 in the (1-2)th unit pixel area PXA1b and the center of the third emission area EA3 in the (4-1)th unit pixel area PXA4a.) and a fourth virtual line VL4 connecting the center of the second emission area EA2 in the (2-1)th unit pixel area PXA2a and the center of the second emission area EA2 in the (3-2)th unit pixel area PXA3b may intersect each other. An angle θ2 between the third virtual line VL3 and the fourth virtual line VL4 may be about 80° to about 100°.

A second virtual line VL2 connecting the centers of the first emission area EA1 in the (2-1)th unit pixel area PXA2a and the first emission area EA1 in the (3-1)th unit pixel area PXA3a may be arranged in a second oblique direction, and a fourth virtual line VL4 connecting the centers of the second emission area EA2 in the (2-1)th unit pixel area PXA2a and the second emission area EA2 in the (3-2)th unit pixel area PXA3b may be arranged in a fourth oblique direction intersecting the second oblique direction.

A first virtual line VL1 connecting the center of the third emission area EA3 in the first unit pixel area PXA1 and the center of the third emission area EA3 in the fourth unit pixel area PXA4 and a second virtual line VL2 connecting the center of the first emission area EA1 in the second unit pixel area PXA2 and the center of the first emission area EA1 in the third unit pixel area PXA3 may intersect each other.

The second emission area EA2 in the (1-1)th unit pixel area PXA1a and the second emission area EA2 in the (4-1)th unit pixel area PXA4a may be arranged adjacent to each other between the third emission area EA3 in the (3-1)th unit pixel area PXA3a and the third emission area EA3 in the (2-1)th unit pixel area PXA2a.

The first emission area EA1 in the (4-1)th unit pixel area PXA4a and the first emission area EA1 in the (1-2)th unit pixel area PXA1b may be arranged adjacent to each other between the third emission area EA3 in the (2-1)th unit pixel area PXA2a and the third emission area EA3 in the (3-2)th unit pixel area PXA3b.

As illustrated in FIG. 6, the pixel electrode 121 may include a first pixel electrode 121a of the first pixel PX1, a second pixel electrode 121b of the second pixel PX2, and a third pixel electrode 121c of the third pixel PX3. The first to third pixel electrodes 121a, 121b, and 121c are illustrated as having a circular shape. However, embodiments are not limited thereto. For example, the first to third pixel electrodes 121a, 121b, and 121c may have a rectangular shape, unlike the shape of the corresponding emission areas EA. For example, the shape of the first to third pixel electrodes 121a, 121b, and 121c may be variously modified, such as a rounded rectangular shape or an elliptical shape.

The emission area EA may be arranged to correspond to (or to overlap) the pixel electrode 121. For example, the arrangement (or disposition) of the pixel electrodes 121 may correspond to the arrangement (or disposition) of the emission area EA described above. The arrangement (or disposition) of the first pixel electrode 121a may correspond to the arrangement (or disposition) of the first emission area EAL. The arrangement (or disposition) of the second pixel electrodes 121b may correspond to the arrangement (or disposition) of the second emission area EA2. The arrangement (or disposition) of the third pixel electrode 121c may correspond to the arrangement (or disposition) of the third emission area EA3.

As illustrated in FIG. 7, the opening OP of the pixel definition layer 119 may include a first opening OP1 exposing a portion of the first pixel electrode 121a, a second opening OP2 exposing a portion of the second pixel electrode 121b, and a third opening OP3 exposing a portion of the third pixel electrode 121c. Because the size and shape of the emission area EA of the organic light emitting diode OLED are defined by the opening OP of the pixel definition layer 119, the shape and arrangement (or disposition) of the first to third openings OP1, OP2, and OP3 may be the same as the shape and arrangement (or disposition) of the first to third emission areas EA1, EA2, and EA3 described above.

As illustrated in FIG. 8, the emission layer 122b may include a first emission layer 122ba of the first pixel PX1, a second emission layer 122bb of the second pixel PX2, and a third emission layer 122bc of the third pixel PX3. The first emission layer 122ba may be disposed over the first pixel electrode 121a, the second emission layer 122bb may be disposed over the second pixel electrode 121b, and the third emission layer 122bc may be disposed over the third pixel electrode 121c.

The emission layer 122b may have a closed curve shape. For example, the third emission layer 122bc may have a circular shape. For example, the first emission layer 122ba and the second emission layer 122bb may have a dumbbell shape (or a peanut shape).

The first emission layer 122ba in the second unit pixel area PXA2 and the first emission layer 122ba in the third unit pixel area PXA3 may be integral with each other. A single first emission layer 122ba may be disposed over the first pixel electrode 121a in the second unit pixel area PXA2 and the first pixel electrode 121a in the third unit pixel area PXA3.

The first emission layer 122ba in the first unit pixel area PXA1 and the first emission layer 122ba in the fourth unit pixel area PXA4 may be integral with each other. A single first emission layer 122ba may be disposed over the first pixel electrode 121a in the first unit pixel area PXA1 and the first pixel electrode 121a in the fourth unit pixel area PXA4.

The first emission layer 122ba of the first pixel PX1 connected between the second unit pixel area PXA2 and the third unit pixel area PXA3 may be arranged in a third oblique direction. The third oblique direction may have an angle greater than about 0° and less than about 900 with respect to the first direction DR1. The first emission layer 122ba of the first pixel PX1 connected between the first unit pixel area PXA1 and the fourth unit pixel area PXA4 may be arranged in a fourth oblique direction intersecting the third oblique direction. The fourth oblique direction may be an oblique direction between the first direction DR1 and the second direction DR2.

The second emission layer 122bb in the first unit pixel area PXA1 and the second emission layer 122bb in the fourth unit pixel area PXA4 may be integral with each other. A single second emission layer 122bb may be disposed over the second pixel electrode 121b in the first unit pixel area PXA1 and the second pixel electrode 121b in the fourth unit pixel area PXA4.

The second emission layer 122bb in the second unit pixel area PXA2 and the second emission layer 122bb in the third unit pixel area PXA3 may be integral with each other. A single second emission layer 122bb may be disposed over the second pixel electrode 121b in the second unit pixel area PXA2 and the second pixel electrode 121b in the third unit pixel area PXA3.

The second emission layer 122bb of the second pixel PX2 connected between the first unit pixel area PXA1 and the fourth unit pixel area PXA4 may be arranged in the third oblique direction. The second emission layer 122bb of the second pixel PX2 connected between the second unit pixel area PXA2 and the third unit pixel area PXA3 may be arranged in the fourth oblique direction intersecting the third oblique direction.

The third emission layer 122bc may be arranged in an area corresponding to the third emission area EA3. The size of the third emission layer 122bc may be greater than the size of the third emission area EA3.

The first emission layer 122ba in the (2-1)th unit pixel area PXA2a and the first emission layer 122ba in the (3-1)th unit pixel area PXA3a may be integral with each other. A single first emission layer 122ba may be disposed over the first pixel electrode 121a in the (2-1)th unit pixel area PXA2a and the first pixel electrode 121a in the (3-1)th unit pixel area PXA3a.

The first emission layer 122ba in the (1-2)th unit pixel area PXA1b and the first emission layer 122ba in the (4-1)th unit pixel area PXA4a may be integral with each other. A single first emission layer 122ba may be disposed over the first pixel electrode 121a in the (1-2)th unit pixel area PXA1b and the first pixel electrode 121a in the (4-1)th unit pixel area PXA4a.

The second emission layer 122bb in the (1-1)th unit pixel area PXA1a and the second emission layer 122bb in the (4-1)th unit pixel area PXA4a may be integral with each other. A single second emission layer 122bb may be disposed over the second pixel electrode 121b in the (1-1)th unit pixel area PXA1a and the second pixel electrode 121b in the (4-1)th unit pixel area PXA4a.

The second emission layer 122bb in the (2-1)th unit pixel area PXA2a and the second emission layer 122bb in the (3-2)th unit pixel area PXA3b may be integral with each other. A single second emission layer 122bb may be disposed over the second pixel electrode 121b in the (2-1)th unit pixel area PXA2a and the second pixel electrode 121b in the (3-2)th unit pixel area PXA3b.

The integrally-provided first emission layer 122ba of the first emission area EA1 in the (2-1)th unit pixel area PXA2a and the first emission area EA1 in the (3-1)th unit pixel area PXA3a may be arranged in a second oblique direction, and the integrally-provided second emission layer 122bb of the second emission area EA2 in the (2-1)th unit pixel area PXA2a and the second emission area EA2 in the (3-2)th unit pixel area PXA3b may be arranged in a fourth oblique direction intersecting the second oblique direction. In the embodiment, because the first emission layer 122ba and the second emission layer 122bb adjacent to each other in the first direction DR1 are arranged in directions intersecting each other, a tensile strain that may occur during the manufacturing process of the display panel 10 may be reduced.

In embodiments, an emission layer of a pair of emission areas arranged adjacent to each other among the emission areas emitting the same color may be integral with each other to improve the manufacturing process efficiency.

In the following embodiments, the same descriptions as those given above will be omitted or simplified and differences therebetween will be described.

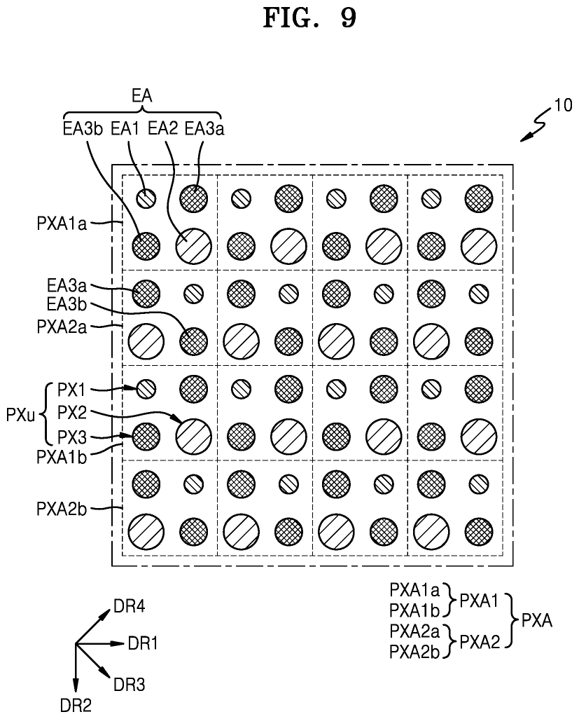

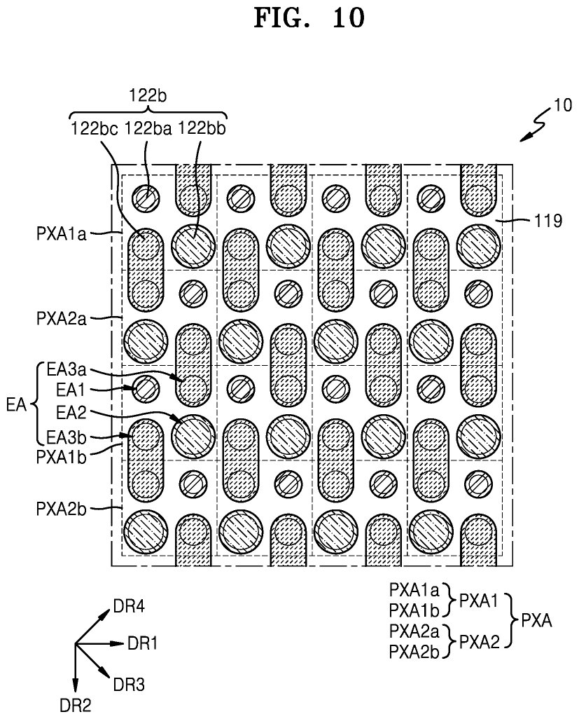

FIG. 9 is a schematic plan view illustrating an arrangement of pixels arranged in a display area of a display panel according to an embodiment. FIG. 9 illustrates emission areas EA corresponding to a first display element of a first pixel PX1, a second display element of a second pixel PX2, and a third display element of a third pixel PX3. FIG. 10 illustrates an arrangement of the emission layers 122b of the first to third pixels PX1, PX2, and PX3 of FIG. 9.

Referring to FIGS. 9 and 10, the unit pixel areas PXA may include a first unit pixel area PXA1 and a second unit pixel area PXA2 alternately arranged in the second direction DR2. Each of the unit pixel areas PXA may include a first emission area EA1, a second emission area EA2, and a pair of third emission areas EA3a and EA3b. In each of the unit pixel areas PXA, one third emission area EA3a may be disposed over the other third emission area EA3b in a plan view.

The first to third emission areas EA1, EA2, EA3a, and EA3b may have a closed curve shape. In an embodiment, the first to third emission areas EA1, EA2, EA3a, and EA3b may have a circular shape. However, embodiments are not limited thereto. For example, the first to third emission areas EA1, EA2, EA3a, and EA3b may have a circular shape, an elliptical shape, or the like. A reflective color band and diffraction phenomenon may be minimized by implementing the first to third emission areas EA1, EA2, EA3a, and EA3b in a closed curve shape.

The area (or size) of the first emission area EA1 may be smaller than the area (or size) of the second emission area EA2. The area (or size) of each of the pair of third emission areas EA3a and EA3b may be greater than the area (or size) of the first emission area EA1 and may be smaller than the area (or size) of the second emission area EA2. The sum of the areas (or sizes) of the pair of third emission areas EA3a and EA3b may be greater than the area (or size) of the first emission area EA1 and may be greater than the area (or size) of the second emission area EA2.

In the first unit pixel area PXA1, the first emission area EA1 and the second emission area EA2 may be arranged adjacent to each other in a third direction DR3 that is an oblique direction. The third direction DR3 may be an oblique direction or a first diagonal direction between the first direction DR1 and the second direction DR2. In the first unit pixel area PXA1, the pair of third emission areas EA3a and EA3b may be arranged adjacent to each other in a fourth direction DR4 that is an oblique direction or a second diagonal direction. The fourth direction DR4 may intersect the third direction DR3. Because the first emission area EA1 and the second emission area EA2 are arranged in the third direction DR3 and the pair of third emission areas EA3a and EA3b are arranged in the fourth direction DR4 intersecting the third direction DR3, the efficiency of the space in which the pixels are arranged may be increased.

In the second unit pixel area PXA2, the first emission area EA1 and the second emission area EA2 may be arranged adjacent to each other in the fourth direction DR4 that is an oblique direction. In the second unit pixel area PXA2, the pair of third emission areas EA3a and EA3b may be arranged adjacent to each other in the third direction DR3 that is an oblique direction.

In the first unit pixel area PXA1, the first emission area EA1, the second emission area EA2, and the pair of third emission areas EA3a and EA3b may be arranged in a fifth arrangement pattern in which virtual lines connecting the respective centers thereof form a rectangle. In the second unit pixel area PXA2, the first emission area EA1, the second emission area EA2, and the pair of third emission areas EA3a and EA3b may be arranged in a sixth arrangement pattern, which is left-right symmetrical to the fifth arrangement pattern.

One third emission area EA3b among the pair of third emission areas EA3a and EA3b in the first unit pixel area PXA1 and one third emission area EA3a among the pair of third emission areas EA3a and EA3b in the second unit pixel area PXA2 may be arranged adjacent to each other in the second direction DR2.

In an embodiment, the second emission area EA2 in the first unit pixel area PXA1 may be arranged adjacent to the first emission area EA1 in the second unit pixel area PXA2 in the second direction DR2.

The first unit pixel area PXA1 may include a (1-1)th unit pixel area PXA1a and a (1-2)th unit pixel area PXA1b spaced apart from each other in the second direction DR2. The second unit pixel area PXA2 may include a (2-1)th unit pixel area PXA2a and a (2-2)th unit pixel area PXA2b spaced apart from each other in the second direction DR2. The (2-1)th unit pixel area PXA2a may be arranged between the (1-1)th unit pixel area PXA1a and the (1-2)th unit pixel area PXA1b.

One third emission area EA3b among the pair of third emission areas EA3a and EA3b in the (1-1)th unit pixel area PXA1a and one third emission area EA3a among the pair of third emission areas EA3a and EA3b in the (2-1)th unit pixel area PXA2a may be arranged adjacent to each other in the second direction DR2. The other third emission area EA3b among the pair of third emission areas EA3a and EA3b in the (2-1)th unit pixel area PXA2a and one third emission area EA3a among the pair of third emission areas EA3a and EA3b in the (1-2)th unit pixel area PXA1b may be arranged adjacent to each other in the second direction DR2.

In an embodiment, the second emission area EA2 in the (1-1)th unit pixel area PXA1a and the first emission area EA1 in the (2-1)th unit pixel area PXA2a may be arranged adjacent to each other in the second direction DR2. In an embodiment, the second emission area EA2 in the (2-1)th unit pixel area PXA2a and the first emission area EA1 in the (1-2)th unit pixel area PXA1b may be arranged adjacent to each other in the second direction DR2.

As illustrated in FIG. 10, the emission layer 122b may include a first emission layer 122ba of the first pixel PX1, a second emission layer 122bb of the second pixel PX2, and a third emission layer 122bc of the third pixel PX3. The first emission layer 122ba may be disposed over a pixel electrode of the first pixel PX1, the second emission layer 122bb may be disposed over a pixel electrode of the second pixel PX2, and the third emission layer 122bc may be disposed over a pixel electrode of the third pixel PX3.

The emission layer 122b may have a closed curve shape. For example, the first emission layer 122ba and the second emission layer 122bb may have a circular shape. For example, the third emission layer 122bc may have a rounded rectangular shape. For example, the third emission layer 122bc may have a shape in which semicircles are combined on sides (e.g., opposite sides) of a rectangle. For example, the third emission layer 122bc may have a dumbbell shape.

The third emission layer 122bc corresponding to the third emission area EA3b in the first unit pixel area PXA1 and the third emission layer 122bc corresponding to the third emission area EA3a in the second unit pixel area PXA2 may be integral with each other. The first emission layer 122ba and the second emission layer 122bb in the first unit pixel area PXA1 may be respectively arranged at positions corresponding to the first emission area EA1 and the second emission area EA2. The first emission layer 122ba and the second emission layer 122bb in the second unit pixel area PXA2 may be respectively arranged at positions corresponding to the first emission area EA1 and the second emission area EA2.

The third emission layer 122bc corresponding to the third emission area EA3b in the (1-1)th unit pixel area PXA1a and the third emission layer 122bc corresponding to the third emission area EA3a in the (2-1)th unit pixel area PXA2a may be integral with each other. The third emission layer 122bc corresponding to the third emission area EA3b in the (2-1)th unit pixel area PXA2a and the third emission layer 122bc corresponding to the third emission area EA3a in the (1-2)th unit pixel area PXA1b may be integral with each other.

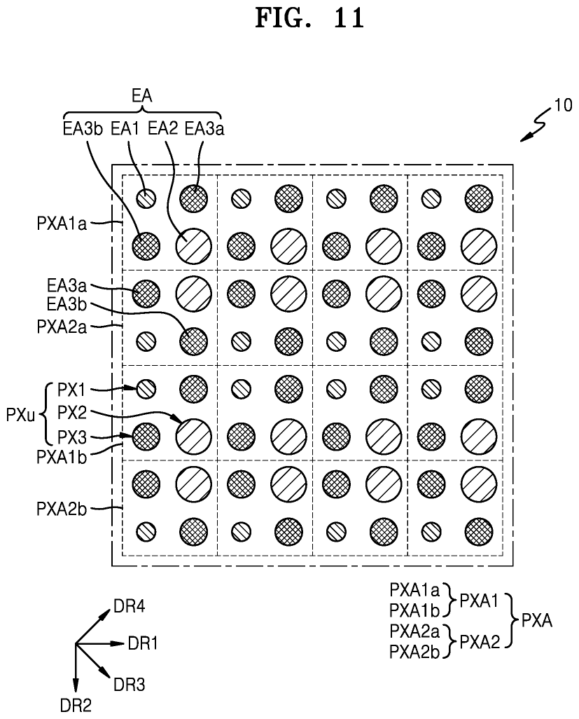

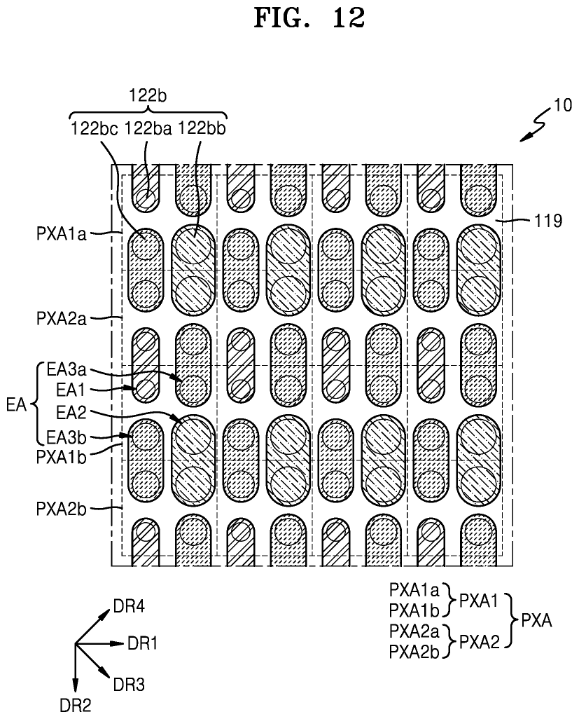

FIG. 11 is a schematic plan view illustrating an arrangement of pixels arranged in a display area of a display panel according to an embodiment. FIG. 11 illustrates emission areas EA corresponding to a first display element of a first pixel PX1, a second display element of a second pixel PX2, and a third display element of a third pixel PX3. FIG. 12 illustrates an arrangement of the emission layers 122b of the first to third pixels PX1, PX2, and PX3 of FIG. 11. In FIGS. 11 and 12, the same descriptions as those given above with reference to FIGS. 9 and 10 will be omitted or simplified and differences therebetween will be described.

Referring to FIGS. 11 and 12, in the first unit pixel area PXA1, the first emission area EA1, the second emission area EA2, and the pair of third emission areas EA3a and EA3b may be arranged in a seventh arrangement pattern in which virtual lines connecting the respective centers thereof form a rectangle. In the second unit pixel area PXA2, the first emission area EA1, the second emission area EA2, and the pair of third emission areas EA3a and EA3b may be arranged in an eighth arrangement pattern, which is top-bottom symmetrical to the seventh arrangement pattern.

One third emission area EA3b among the pair of third emission areas EA3a and EA3b in the first unit pixel area PXA1 and one third emission area EA3a among the pair of third emission areas EA3a and EA3b in the second unit pixel area PXA2 may be arranged adjacent to each other in the second direction DR2.

In an embodiment, the second emission area EA2 in the first unit pixel area PXA1 may be arranged adjacent to the second emission area EA2 in the second unit pixel area PXA2 in the second direction DR2. In another example, the first emission area EA1 in the first unit pixel area PXA1 may be arranged adjacent to the first emission area EA1 in the second unit pixel area PXA2 in the second direction DR2.

The first unit pixel area PXA1 may include a (1-1)th unit pixel area PXA1a and a (1-2)th unit pixel area PXA1b spaced apart from each other in the second direction DR2. The second unit pixel area PXA2 may include a (2-1)th unit pixel area PXA2a and a (2-2)th unit pixel area PXA2b spaced apart from each other in the second direction DR2. The (2-1)th unit pixel area PXA2a may be arranged between the (1-1)th unit pixel area PXA1a and the (1-2)th unit pixel area PXA1b.

One third emission area EA3b among the pair of third emission areas EA3a and EA3b in the (1-1)th unit pixel area PXA1a and one third emission area EA3a among the pair of third emission areas EA3a and EA3b in the (2-1)th unit pixel area PXA2a may be arranged adjacent to each other in the second direction DR2. The other third emission area EA3b among the pair of third emission areas EA3a and EA3b in the (2-1)th unit pixel area PXA2a and one third emission area EA3a among the pair of third emission areas EA3a and EA3b in the (1-2)th unit pixel area PXA1b may be arranged adjacent to each other in the second direction DR2.

In an embodiment, the second emission area EA2 in the (1-1)th unit pixel area PXA1a and the second emission area EA2 in the (2-1)th unit pixel area PXA2a may be arranged adjacent to each other in the second direction DR2. In another example, the first emission area EA1 in the (2-1)th unit pixel area PXA2a and the first emission area EA1 in the (1-2)th unit pixel area PXA1b may be arranged adjacent to each other in the second direction DR2.

In the embodiment, it is illustrated that the third emission area EA3 of the (1-1)th unit pixel area PXA1a and the third emission area EA3 of the (2-1)th unit pixel area PXA2a are adjacent to each other and the second emission area EA2 of the (1-1)th unit pixel area PXA1a and the second emission area EA2 of the (2-1)th unit pixel area PXA2a are adjacent to each other. However, embodiments are not limited thereto. In another example, the third emission area EA3 of the (1-1)th unit pixel area PXA1a and the third emission area EA3 of the (2-1)th unit pixel area PXA2a may be arranged adjacent to each other and the first emission area EA1 in the (1-1)th unit pixel area PXA1a and the first emission area EA1 in the (2-1)th unit pixel area PXA2a may be arranged adjacent to each other in the second direction DR2. For example, the second emission area EA2 in the (1-1)th unit pixel area PXA1a and the second emission area EA2 in the (1-2)th unit pixel area PXA1b may be arranged adjacent to each other in the second direction DR2.

As illustrated in FIG. 12, the emission layer 122b may include a first emission layer 122ba of the first pixel PX1, a second emission layer 122bb of the second pixel PX2, and a third emission layer 122bc of the third pixel PX3. The first emission layer 122ba may be disposed over a pixel electrode of the first pixel PX1, the second emission layer 122bb may be disposed over a pixel electrode of the second pixel PX2, and the third emission layer 122bc may be disposed over a pixel electrode of the third pixel PX3.

The emission layer 122b may have a closed curve shape. For example, the first to third emission layers 122ba, 122bb, and 122bc may have a rounded rectangular shape. For example, the first to third emission layers 122ba, 122bb, and 122bc may have a shape in which semicircles are combined on sides (e.g., opposite sides) of a rectangle. For example, the first to third emission layers 122ba, 122bb, and 122bc may have a dumbbell shape.

In the embodiment, the emission layer 122 of pixels arranged adjacent to each other among the pixels emitting the same light may be integral with each other. In an embodiment, the first emission layer 122ba of the first emission areas EA1 arranged adjacent to each other may be integral with each other. In an embodiment, the second emission layer 122bb of the second emission areas EA2 arranged adjacent to each other may be integral with each other. In an embodiment, the third emission layer 122bc of the third emission areas EA3 arranged adjacent to each other may be integral with each other.

The third emission layer 122bc corresponding to the third emission area EA3b in the first unit pixel area PXA1 and the third emission layer 122bc corresponding to the third emission area EA3a in the second unit pixel area PXA2 may be integral with each other. In an embodiment, the second emission layer 122bb corresponding to the second emission area EA2 in the first unit pixel area PXA1 and the second emission layer 122bb corresponding to the second emission area EA2 in the second unit pixel area PXA2 may be integral with each other. In an embodiment, the first emission layer 122ba corresponding to the first emission area EA1 in the first unit pixel area PXA1 and the first emission layer 122ba corresponding to the first emission area EA1 in the second unit pixel area PXA2 may be integral with each other.

In an embodiment, the second emission layer 122bb corresponding to the second emission area EA2 in the (1-1)th unit pixel area PXA1a and the second emission layer 122bb corresponding to the second emission area EA2 in the (2-1)th unit pixel area PXA2a may be integral with each other. For example, the first emission layer 122ba corresponding to the first emission area EA1 in the (2-1)th unit pixel area PXA2a and the first emission layer 122ba corresponding to the first emission area EA1 in the (1-2)th unit pixel area PXA1b may be integral with each other.

In another example, the first emission layer 122ba corresponding to the first emission area EA1 in the (1-1)th unit pixel area PXA1a and the first emission layer 122ba corresponding to the first emission area EA1 in the (2-1)th unit pixel area PXA2a may be integral with each other. For example, the second emission layer 122bb corresponding to the second emission area EA2 in the (2-1)th unit pixel area PXA2a and the second emission layer 122bb corresponding to the second emission area EA2 in the (1-2)th unit pixel area PXA1b may be integral with each other.

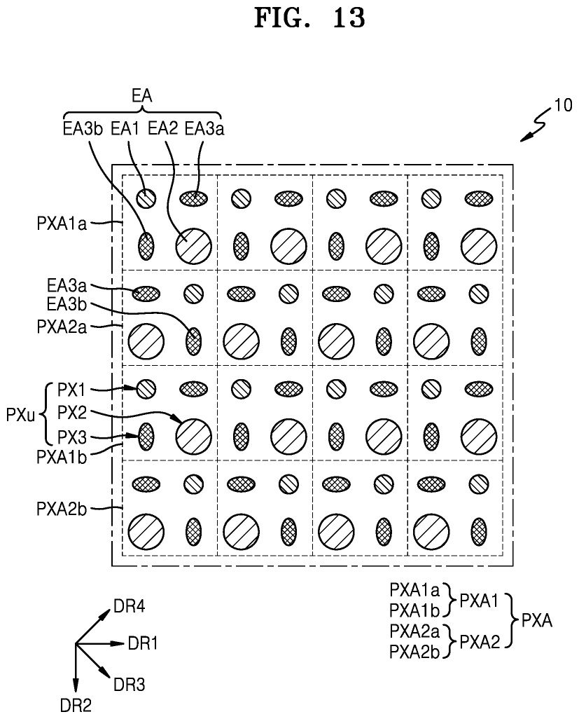

FIG. 13 is a schematic plan view illustrating an arrangement of pixels arranged in a display area of a display panel according to an embodiment. Because the arrangement (or disposition) of emission areas EA of FIG. 13 are the same as the arrangement (or disposition) of the emission areas EA described above with reference to FIGS. 9 and 10, redundant descriptions thereof will be omitted and differences therebetween will be described.

Referring to FIG. 13, the third emission area EA3 may have an elliptical shape. In an embodiment, the first emission area EA1 and the second emission area EA2 may have a circular shape. However, embodiments are not limited thereto. For example, the first emission area EA1 and the second emission area EA2 may have a closed curve shape such as an elliptical shape or a rounded polygonal shape. Because the third emission area EA3 is formed in an elliptical shape, the display quality may be improved with minimizing the aperture ratio loss of the display panel 10.

In an embodiment, one third emission area EA3a among the pair of third emission areas EA3a and EA3b in the first unit pixel area PXA1 may have a long axis arranged in the first direction DR1. For example, the other third emission area EA3b among the pair of third emission areas EA3a and EA3b in the first unit pixel area PXA1 may have a long axis arranged in the second direction DR2.

In an embodiment, the third emission area EA3b in the first unit pixel area PXA1 and the third emission area EA3a in the second unit pixel area PXA2 arranged adjacent to each other in the second direction DR2 may have long axes arranged in different directions. For example, one third emission area EA3b among the pair of third emission areas EA3a and EA3b in the first unit pixel area PXA1 may have a long axis arranged in the second direction DR2 and the third emission area EA3a adjacent to the third emission area EA3b of the first unit pixel area PXA1 in the second unit pixel area PXA2 may have a long axis arranged in the first direction DR1. For example, one third emission area EA3b among the pair of third emission areas EA3a and EA3b in the first unit pixel area PXA1 may have a long axis arranged in the first direction DR1 and the third emission area EA3a adjacent to the third emission area EA3b of the first unit pixel area PXA1 in the second unit pixel area PXA2 may have a long axis arranged in the second direction DR2.

The first unit pixel area PXA1 may include a (1-1)th unit pixel area PXA1a and a (1-2)th unit pixel area PXA1b spaced apart from each other in the second direction DR2. The second unit pixel area PXA2 may include a (2-1)th unit pixel area PXA2a and a (2-2)th unit pixel area PXA2b spaced apart from each other in the second direction DR2. The (2-1)th unit pixel area PXA2a may be arranged between the (1-1)th unit pixel area PXA1a and the (1-2)th unit pixel area PXA1b.

In an embodiment, the third emission area EA3b in the (1-1)th unit pixel area PXA1a and the third emission area EA3a in the (2-1)th unit pixel area PXA2a arranged adjacent to each other in the second direction DR2 may have long axes arranged in different directions. For example, one third emission area EA3b among the pair of third emission areas EA3a and EA3b in the (1-1)th unit pixel area PXA1a may have a long axis arranged in the second direction DR2 and the third emission area EA3a adjacent to the third emission area EA3b of the first unit pixel area PXA1 in the (2-1)th unit pixel area PXA2a may have a long axis arranged in the first direction DR1. In an embodiment, the third emission area EA3b in the (2-1)th unit pixel area PXA2a and the third emission area EA3a in the (1-2)th unit pixel area PXA1b arranged adjacent to each other in the second direction DR2 may have long axes arranged in different directions. For example, one third emission area EA3b among the pair of third emission areas EA3a and EA3b in the (2-1)th unit pixel area PXA2a may have a long axis arranged in the second direction DR2 and the third emission area EA3a adjacent to the third emission area EA3b of the first unit pixel area PXA1 in the (1-2)th unit pixel area PXA1b may have a long axis arranged in the first direction DR1.

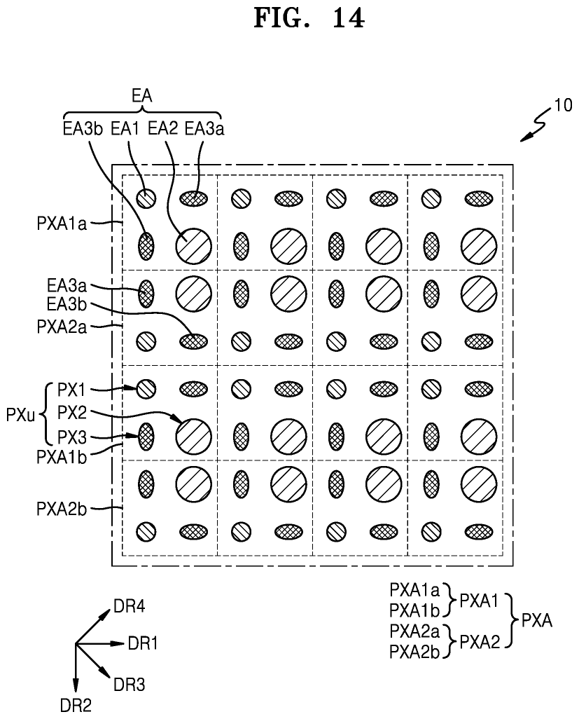

FIG. 14 is a schematic plan view illustrating an arrangement of pixels arranged in a display area of a display panel according to an embodiment. Because the arrangement (or disposition) of emission areas EA of FIG. 14 are the same as the arrangement (or disposition) of the emission areas EA described above with reference to FIGS. 11 and 12, redundant descriptions thereof will be omitted and differences therebetween will be described.

Referring to FIG. 14, the third emission area EA3 may have an elliptical shape. In an embodiment, the first emission area EA1 and the second emission area EA2 may have a circular shape. However, embodiments are not limited thereto. For example, the first emission area EA1 and the second emission area EA2 may have a closed curve shape such as an elliptical shape or a rounded polygonal shape.

In an embodiment, one third emission area EA3a among the pair of third emission areas EA3a and EA3b in the first unit pixel area PXA1 may have a long axis arranged in the first direction DR1. For example, the other third emission area EA3b among the pair of third emission areas EA3a and EA3b in the first unit pixel area PXA1 may have a long axis arranged in the second direction DR2.

In an embodiment, the third emission area EA3b in the first unit pixel area PXA1 and the third emission area EA3a in the second unit pixel area PXA2 arranged adjacent to each other in the second direction DR2 may have long axes arranged in the same direction. For example, one third emission area EA3b among the pair of third emission areas EA3a and EA3b in the first unit pixel area PXA1 may have a long axis arranged in the second direction DR2 and the third emission area EA3a adjacent to the third emission area EA3b of the first unit pixel area PXA1 in the second unit pixel area PXA2 may have a long axis arranged in the second direction DR2. For example, one third emission area EA3b among the pair of third emission areas EA3a and EA3b in the first unit pixel area PXA1 may have a long axis arranged in the first direction DR1 and the third emission area EA3a adjacent to the third emission area EA3b of the first unit pixel area PXA1 in the second unit pixel area PXA2 may have a long axis arranged in the first direction DR1.

In an embodiment, the third emission area EA3b in the (1-1)th unit pixel area PXA1a and the third emission area EA3a in the (2-1)th unit pixel area PXA2a arranged adjacent to each other in the second direction DR2 may have long axes arranged in the same direction. In an embodiment, the third emission area EA3b in the (2-1)th unit pixel area PXA2a and the third emission area EA3a in the (1-2)th unit pixel area PXA1b arranged adjacent to each other in the second direction DR2 may have long axes arranged in the same direction. In an embodiment, one third emission area EA3b among the pair of third emission areas EA3a and EA3b in the (1-1)th unit pixel area PXA1a may have a long axis arranged in the second direction DR2 and the third emission area EA3a adjacent to the third emission area EA3b of the first unit pixel area PXA1 in the (2-1)th unit pixel area PXA2a may have a long axis arranged in the second direction DR2. For example, one third emission area EA3b among the pair of third emission areas EA3a and EA3b in the (2-1)th unit pixel area PXA2a may have a long axis arranged in the first direction DR1 and the third emission area EA3a adjacent to the third emission area EA3b of the first unit pixel area PXA1 in the (1-2)th unit pixel area PXA1b may have a long axis arranged in the first direction DR1.

Because the shape of the emission area according to embodiments has minimized straight lines and curved edges, a reflective color band and diffraction phenomenon may be minimized.

For convenience, the display apparatus including the organic light emitting diode as a display element has been described above. However, embodiments may be applied to various types of display apparatuses such as liquid crystal display apparatuses, electrophoretic display apparatuses, and inorganic EL display apparatuses.

The display apparatus according to embodiments may be implemented as an electronic apparatus such as a smart phone, a mobile phone, a smart watch, a navigation apparatus, a game machine, a television (TV), a vehicle head unit, a notebook computer, a laptop computer, a tablet computer, a personal media player (PMP), or a personal digital assistant (PDA). Also, the electronic apparatus may be a flexible apparatus.

According to embodiments, a display apparatus with improved display quality may be provided by implementing an emission area in a closed curve shape. However, the scope of the disclosure is not limited to these effects.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display panel comprising:
unit pixel areas arranged in a first direction and a second direction perpendicular to the first direction, wherein
a first display element emitting light of a first color, a second display element emitting light of a second color, and a third display element emitting light of a third color are arranged in each of the unit pixel areas,
the unit pixel areas comprise:
a first unit pixel area and a second unit pixel area alternately arranged in the first direction, and
a third unit pixel area and a fourth unit pixel area respectively adjacent to the first unit pixel area and the second unit pixel area in the second direction,
in the first unit pixel area, a first emission area corresponding to the first display element, a second emission area corresponding to the second display element, and a third emission area corresponding to the third display element are arranged in a first arrangement pattern such that virtual lines connecting respective centers of the first, second, and third emission areas form a triangle,
in the second unit pixel area, the first emission area, the second emission area, and the third emission area are arranged in a second arrangement pattern, which is top-bottom symmetrical to the first arrangement pattern,
in the third unit pixel area, the first emission area, the second emission area, and the third emission area are arranged in a third arrangement pattern, which is left-right symmetrical to the first arrangement pattern,
in the fourth unit pixel area, the first emission area, the second emission area, and the third emission area are arranged in a fourth arrangement pattern, which is top-bottom symmetrical to the third arrangement pattern, and
each of the first emission area, the second emission area, and the third emission area has a closed curve shape.

2. The display panel of claim 1, wherein
the first emission area and the second emission area are arranged adjacent to each other in the first direction, and
the third emission area is arranged adjacent to the first emission area and the second emission area in the second direction.

3. The display panel of claim 2, wherein a size of the third emission area is greater than a size of the first emission area and a size of the second emission area.

4. The display panel of claim 3, wherein the size of the first emission area and the size of the second emission area are substantially equal to each other.

5. The display panel of claim 3, wherein the size of the first emission area and the size of the second emission area are different from each other.

6. The display panel of claim 3, wherein the first emission area in the second unit pixel area and the first emission area in the third unit pixel area are arranged adjacent to each other between the third emission area in the first unit pixel area and the third emission area in the fourth unit pixel area.

7. The display panel of claim 6, wherein an emission layer of the first display element in the second unit pixel area and an emission layer of the first display element in the third unit pixel area are integral with each other.

8. The display panel of claim 6, wherein a distance between the third emission area in the first unit pixel area and the third emission area in the fourth unit pixel area is greater than a distance between the first emission area in the second unit pixel area and the first emission area in the third unit pixel area.

9. The display panel of claim 6, wherein an angle between a virtual straight line connecting a center of the third emission area in the first unit pixel area and a center of the third emission area in the fourth unit pixel area and a virtual straight line connecting a center of the first emission area in the second unit pixel area and a center of the first emission area in the third unit pixel area is in a range of about 80° to about 100°.

10. The display panel of claim 3, wherein
the first unit pixel area comprises a (1-1)th unit pixel area and a (1-2)th unit pixel area spaced apart from each other in the first direction,
the second unit pixel area comprises a (2-1)th unit pixel area arranged between the (1-1)th unit pixel area and the (1-2)th unit pixel area,
the third unit pixel area comprises a (3-1)th unit pixel area and a (3-2)th unit pixel area respectively adjacent to the (1-1)th unit pixel area and the (1-2)th unit pixel area in the second direction,
the fourth unit pixel area comprises a (4-1)th unit pixel area adjacent to the (2-1)th unit pixel area in the second direction,
the first emission area in the (2-1)th unit pixel area and the first emission area in the (3-1)th unit pixel area are arranged to be adjacent to each other between the third emission area in the (1-1)th unit pixel area and the third emission area in the (4-1)th unit pixel area, and the second emission area in the (2-1)th unit pixel area and the second emission area in the (3-2)th unit pixel area are arranged to be adjacent to each other between the third emission area in the (1-2)th unit pixel area and the third emission area in the (4-1)th unit pixel area.

11. The display panel of claim 10, wherein
an emission layer of the first display element in the (2-1)th unit pixel area and an emission layer of the first display element in the (3-1)th unit pixel area are integral with each other, and
an emission layer of the second display element in the (2-1)th unit pixel area and an emission layer of the second display element in the (3-2)th unit pixel area are integral with each other.

12. The display panel of claim 10, wherein
a virtual line connecting centers of the first emission area in the (2-1)th unit pixel area and the first emission area in the (3-1)th unit pixel area is arranged in a first oblique direction, and
a virtual line connecting centers of the second emission area in the (2-1)th unit pixel area and the second emission area in the (3-2)th unit pixel area is arranged in a second oblique direction intersecting the first oblique direction.

13. The display panel of claim 3, wherein
the first emission area in the first unit pixel area, the second emission area in the first unit pixel area, and the third emission area in the second unit pixel area are arranged in a virtual line in the first direction,
the third emission area in the first unit pixel area, the first emission area in the second unit pixel area, and the second emission area in the second unit pixel area are arranged in a virtual line in the first direction,
the second emission area in the third unit pixel area, the first emission area in the third unit pixel area, and the third emission area in the fourth unit pixel area are arranged in a virtual line in the first direction, and
the third emission area in the third unit pixel area, the second emission area in the fourth unit pixel area, and the first emission area in the fourth unit pixel area are arranged in a virtual line in the first direction.

14. The display panel of claim 13, wherein
the first emission area in the first unit pixel area and the second emission area in the third unit pixel area are arranged in a virtual line in the second direction,
the third emission area in the first unit pixel area and the third emission area in the third unit pixel area are arranged in a virtual line in the second direction,
the second emission area in the first unit pixel area and the first emission area in the third unit pixel area are arranged in a virtual line in the first direction,
the first emission area in the second unit pixel area and the second emission area in the fourth unit pixel area are arranged in a virtual line in the second direction,
the third emission area in the second unit pixel area and the third emission area in the fourth unit pixel area are arranged in a virtual line in the second direction, and
the second emission area in the second unit pixel area and the first emission area in the fourth unit pixel area are arranged in a virtual line in the second direction.

15. A display panel comprising:
unit pixel areas arranged in a first direction and a second direction perpendicular to the first direction, wherein
a first display element emitting light of a first color, a second display element emitting light of a second color, and a pair of third display elements emitting light of a third color are arranged in each of the unit pixel areas,
the unit pixel areas comprise a first unit pixel area and a second unit pixel area alternately arranged in the second direction,
in the first unit pixel area, a first emission area corresponding to the first display element and a second emission area corresponding to the second display element are arranged adjacent to each other in a first diagonal direction and a pair of third emission areas respectively corresponding to the pair of third display elements are arranged adjacent to each other in a second diagonal direction,
in the second unit pixel area, the first emission area and the second emission area are arranged adjacent to each other in the second diagonal direction and the pair of third emission areas are arranged adjacent to each other in the first diagonal direction,
a third emission area among the pair of third emission areas in the first unit pixel area and a third emission area among the pair of third emission areas in the second unit pixel area are arranged adjacent to each other in the second direction,
the first emission area has a size smaller than a size of the second emission area, and
each of the pair of third emission areas has a size greater than the size of the first emission area and smaller than the size of the second emission area, and
each of the first emission area, the second emission area, and the pair of third emission areas has a closed curve shape.

16. The display panel of claim 15, wherein a sum of the sizes of the pair of third emission areas is greater than the size of the first emission area and greater than the size of the second emission area.

17. The display panel of claim 15, wherein each of the pair of third emission areas has an elliptical shape.

18. The display panel of claim 17, wherein
one third emission area among the pair of third emission areas in the first unit pixel area has a long axis arranged in the first direction, and
another third emission area among the pair of third emission areas in the first unit pixel area has a long axis arranged in the second direction.

19. The display panel of claim 17, wherein third emission areas, which are arranged adjacent to each other and disposed in the first unit pixel area and the second unit pixel area, respectively, have long axes in different directions.

20. The display panel of claim 17, wherein third emission areas, which are arranged adjacent to each other and disposed in the first unit pixel area and the second unit pixel area, respectively, have long axes in a same direction.

21. The display panel of claim 17, wherein each of the first emission area and the second emission area has a circular shape.

22. The display panel of claim 15, wherein the second emission area in the first unit pixel area and the second emission area in the second unit pixel area are arranged adjacent to each other in the second direction.
